(19) United States
(12) Patent Application Publication
(10) Pub. No.: US 2026/0143585 A1
(43) Pub. Date: May 21, 2026

(54) STRETCHABLE SUBSTRATE, STRETCHABLE DEVICE, AND METHOD FOR PRODUCING SAME

(71) Applicant: Murata Manufacturing Co., Ltd., Nagaokakyo-shi (JP)

(72) Inventor: Hayato KATSU, Nagaokakyo-shi (JP)

(21) Appl. No.: 19/447,523

(22) Filed: Jan. 13, 2026

Related U.S. Application Data
(63) Continuation of application No. PCT/JP2024/025107, filed on Jul. 11, 2024.

(30) Foreign Application Priority Data
Jul. 18, 2023 (JP) 2023-116845

(51) Int. Cl. H05K 1/02

(52) U.S. Cl. CPC H05K 1/0283

(57) ABSTRACT

A stretchable substrate having a first main surface and a second main surface facing opposite of each other, wherein the stretchable substrate satisfies at least one of (1) to (4): (1) at least either the first main surface or the second main surface has an oxygen atomic proportion of 5 at % or more with respect to all atoms as measured by X-ray photoelectron spectroscopy; (2) the first main surface or the second main surface has an arithmetic average surface roughness of 6 μm or more as measured with a laser microscope; (3) at least either the first main surface or the second main surface includes a metal-containing portion containing a metal atom; or (4) a metal-containing region containing a metal atom that is positioned along at least either the first main surface or the second main surface.

### CROSS REFERENCE TO RELATED APPLICATIONS

The present application is a continuation of International application No. PCT/JP2024/025107, filed Jul. 11, 2024, which claims priority to Japanese Patent Application No. 2023-116845, filed Jul. 18, 2023, the entire contents of each of which are incorporated herein by reference.

### TECHNICAL FIELD

The present disclosure relates to a stretchable substrate, a stretchable device, and a method for producing the same.

### BACKGROUND ART

Conventionally, as a stretchable substrate, a fluorine rubber molded body or an elastomer described in Japanese Patent Application Laid-Open No. 2002-293950 (Patent Document 1) has been used. In the document, the fluorine rubber molded body contains 0.01 to 10 parts by weight of silica powder with respect to 100 parts by weight of fluorine rubber, has a crosslinked structure with a polyamine-based crosslinking agent, and has a wrinkled fine uneven structure on its surface. Such a stretchable substrate has moderate stretchability. Further, as a result of having a wrinkled fine uneven structure on its surface, the frictional resistance on the surface of the stretchable substrate has been low.
Patent Document 1: Japanese Patent Application Laid-Open No. 2002-293950

### SUMMARY OF THE DISCLOSURE

To produce a stretchable substrate having low tackiness like a conventional stretchable substrate, it is necessary to separately add a composition containing an inorganic filler such as silica. In such a stretchable substrate, for example, by containing silica, the characteristics of the stretchable substrate can be changed. For example, there is a concern that the stretching characteristics change, and the stretchable substrate plastically deforms, specifically, the permanent strain increases.

An object of the present disclosure is to provide a stretchable substrate that can suppress permanent strain and at the same time suppress autohesion on a surface, a stretchable device, and a method for producing the stretchable substrate and the stretchable device.

To achieve the object, a stretchable substrate according to an aspect of the present disclosure is a stretchable substrate having a first main surface and a second main surface facing opposite of each other, wherein the stretchable substrate satisfies at least one of (1) to (4): (1) at least either the first main surface or the second main surface has an oxygen atomic proportion of 5 at % or more with respect to all atoms as measured by X-ray photoelectron spectroscopy; (2) the first main surface or the second main surface has an arithmetic average surface roughness of 6 μm or more as measured with a laser microscope; (3) at least either the first main surface or the second main surface includes a metal-containing portion containing a metal atom; (4) a metal-containing region containing a metal atom that is positioned along at least either the first main surface or the second main surface.

With the configuration, a stretchable substrate having a modified surface is obtained. As a result, tackiness and autohesion of the stretchable substrate can be suppressed.

The stretchable substrate according to an aspect of the present disclosure includes a first main surface and a second main surface facing opposite of each other, wherein an oxygen atomic proportion of at least either the first main surface or the second main surface is 5 at % or more with respect to all atoms as measured by the X-ray photoelectron spectroscopy.

With the configuration, a stretchable substrate having a modified surface is obtained. As a result, tackiness and autohesion of the stretchable substrate can be suppressed.

The stretchable substrate according to an aspect of the present disclosure includes a first main surface and a second main surface facing opposite of each other, wherein an arithmetic average surface roughness of the surface of the first main surface or the second main surface is 6 μm or more as measured with a laser microscope.

With the configuration, a stretchable substrate having a modified surface is obtained. As a result, autohesion of the stretchable substrate can be suppressed.

The stretchable substrate according to an aspect of the present disclosure includes a first main surface and a second main surface facing opposite of each other, wherein at least either the first main surface or the second main surface includes a metal-containing portion containing a metal atom.

When at least either the first main surface or the second main surface of the stretchable substrate has a metal-containing portion, molecular diffusion causing autohesion is suppressed, and autohesion of the stretchable substrate can be suppressed. Here, the metal-containing portion means a portion containing a metal-containing compound.

A stretchable substrate including a first main surface and a second main surface facing opposite of each other, wherein the metal-containing portion containing the metal atom is positioned along at least either the first main surface or the second main surface.

With the configuration, molecular diffusion causing autohesion is suppressed, and autohesion of the stretchable substrate can be suppressed. Further, the metal-containing portion adheres to a printed circuit other than the stretchable substrate to improve the close contact force between the stretchable base material and another base material.

A stretchable device according to an aspect of the present disclosure includes the stretchable substrate of the present disclosure and a wire disposed on the first main surface of the stretchable substrate.

With the configuration, a stretchable device in which tackiness and autohesion are suppressed can be provided.

The stretchable device according to an aspect of the present disclosure further includes a protective layer.

With the configuration, the wire can be protected.

A method for producing a stretchable substrate according to an aspect of the present disclosure includes: preparing a base material; and performing an ozone treatment on at least either a first main surface of the base material or a second main surface positioned on an opposite side from the first main surface.

By performing the steps, a stretchable substrate containing an oxygen atom can be formed. As a result, the surface of the base material is modified, and tackiness and autohesion of the stretchable substrate can be suppressed.

A method for producing a stretchable device according to an aspect of the present disclosure includes: preparing a base material having a first main surface and a second main surface facing opposite of each other; disposing a wire on the first main surface of the base material; and performing an ozone treatment on at least either the first main surface or the second main surface after the disposing of the wire.

By performing the steps, a stretchable device in which autohesion is suppressed can be formed. In addition, ozone treatment can be performed in a state where the stretchable device has a wire, and the production method can be simplified.

A method for producing a stretchable device according to an aspect of the present disclosure includes: preparing a base material having a first main surface and a second main surface facing opposite of each other; disposing a wire on the first main surface of the base material; and embossing at least either the first main surface or the second main surface after the disposing of the wire.

By performing the steps, autohesion on the surface of the stretchable device can be suppressed. In addition, embossing can be performed in a state where the device has a wire, and the production method can be simplified.

A method for producing a stretchable device according to an aspect of the present disclosure includes: preparing a first base material having a first main surface and a second main surface facing opposite of each other; and forming a metal-containing portion in at least the second main surface of the first base material.

A method for producing a stretchable device according to an aspect of the present disclosure includes: preparing a base material; and forming a metal-containing portion on at least either a first main surface of the base material or a second main surface positioned in an opposite side from the first main surface.

When at least either the first main surface or the second main surface of the stretchable substrate has a metal-containing portion, molecular diffusion causing autohesion is suppressed, and autohesion of the stretchable device can be suppressed.

A method for producing a stretchable device according to an aspect of the present disclosure includes: preparing a first base material having a first main surface and a second main surface facing opposite of each other; disposing a wire on the first main surface of the first base material; and forming a metal-containing portion in at least either the second main surface of the first base material.

By performing the steps, a stretchable device in which autohesion is suppressed can be formed.

According to the present disclosure, a stretchable substrate that can suppress permanent strain and at the same time suppress autohesion on a surface, a stretchable device, and a method for producing the stretchable substrate and the stretchable device can be provided.

### BRIEF EXPLANATION OF THE DRAWINGS

FIG. 1 is a partial top view of a stretchable device according to a first embodiment.

FIG. 2 is a sectional view taken along the line II-II in FIG. 1.

FIG. 3A is an explanatory view for describing a method for producing the stretchable device according to the first embodiment.

FIG. 3B is an explanatory view for describing the method for producing the stretchable device according to the first embodiment.

FIG. 3C is an explanatory view for describing the method for producing the stretchable device according to the first embodiment.

FIG. 4 is a sectional view of a stretchable device according to a second embodiment.

FIG. 5A is a schematic view illustrating a first main surface of a stretchable substrate according to the second embodiment.

FIG. 5B is a schematic view illustrating an embossing sheet material for forming the first main surface of the stretchable substrate according to the second embodiment.

FIG. 6A is an explanatory view for describing a method for producing the stretchable device according to the second embodiment.

FIG. 6B is an explanatory view for describing the method for producing the stretchable device according to the second embodiment.

FIG. 6C is an explanatory view for describing the method for producing the stretchable device according to the second embodiment.

FIG. 7A is a schematic view of a first modification illustrating the first main surface of the stretchable substrate according to the second embodiment.

FIG. 7B is a schematic view illustrating an embossing sheet material of the first modification for forming the first main surface of the stretchable substrate according to the second embodiment.

FIG. 8A is a schematic view illustrating a modification of the embossing sheet material.

FIG. 8B is a schematic view illustrating a modification of the embossing sheet material.

FIG. 8C is a schematic view illustrating a modification of the embossing sheet material.

FIG. 8D is a schematic view illustrating a modification of the embossing sheet material.

FIG. 9 is a sectional view of a stretchable device according to a third embodiment.

FIG. 10A is an explanatory view for describing a method for producing the stretchable device according to the third embodiment.

FIG. 10B is an explanatory view for describing the method for producing the stretchable device according to the third embodiment.

FIG. 10C is an explanatory view for describing the method for producing the stretchable device according to the third embodiment.

FIG. 11 is a sectional view of a first modification of the third embodiment.

FIG. 12 is a sectional view of a second modification of the third embodiment.

FIG. 13 is a sectional view of a stretchable device according to a fourth embodiment.

FIG. 14A is an explanatory view for describing a method for producing the stretchable device according to the fourth embodiment.

FIG. 14B is an explanatory view for describing the method for producing the stretchable device according to the fourth embodiment.

FIG. 14C is an explanatory view for describing the method for producing the stretchable device according to the fourth embodiment.

FIG. 15 is an explanatory view illustrating the surface roughness of a stretchable substrate of Example 15.

FIG. 16 is an explanatory view for describing a portion having a hard phase of a stretchable substrate of Example 19.

FIG. 17 is an explanatory view for describing a measurement method in a peel test.

FIG. 18 is a measurement diagram illustrating the relationship between the moving distance and the peel strength in the peel test in Example 40 and Comparative Example 5.

FIG. 19 is a measurement diagram illustrating the relationship between the press temperature and the peel strength in the peel test.

### DESCRIPTION OF THE PREFERRED EMBODIMENTS

Hereinafter, a stretchable device according to an aspect of the present disclosure will be described in detail with reference to the illustrated embodiments. The drawings include partially schematic drawings, and the drawings do not reflect actual dimensions or ratios in some cases.

A stretchable device of the present disclosure includes a stretchable substrate and a wire provided on a first main surface of the stretchable substrate.

The stretchable substrate is a stretchable substrate including a first main surface and a second main surface facing opposite of each other, wherein the stretchable substrate satisfies at least one of (1) to (4):
at least either the first main surface or the second main surface has an oxygen atomic proportion of 5 at % or more with respect to all atoms as measured by X-ray photoelectron spectroscopy;
the first main surface or the second main surface has an arithmetic average surface roughness of a surface of 6 μm or more as measured with a laser microscope;
at least either the first main surface or the second main surface includes a metal-containing portion containing a metal atom;
a metal-containing region containing a metal atom is positioned along at least either the first main surface or the second main surface. Hereinafter, each of (1) to (4) will be described as a specific embodiment.

### First Embodiment

### [Configuration]

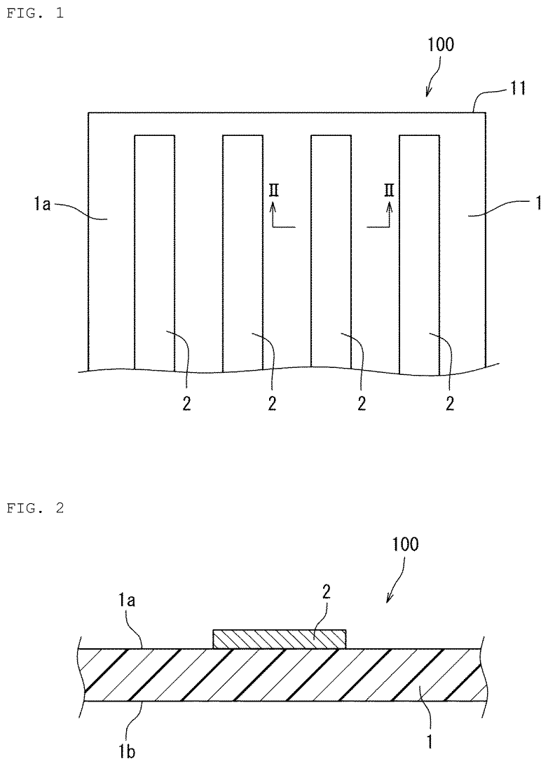

A structure of a stretchable device 100 according to a first embodiment will be described with reference to FIGS. 1 and 2. FIG. 1 is a partial top view of the stretchable device 100. FIG. 2 is a sectional view of the stretchable device 100 taken along the line II-II in FIG. 1.

As illustrated in FIGS. 1 and 2, the stretchable device 100 includes a stretchable substrate 1 and a wire 2 provided on a first main surface 1a of the stretchable substrate 1.

The shape of the stretchable device 100 is not particularly limited. In the present specification, a structure in which one stretchable substrate is connected to the stretchable device 100 will be described as an example, but two or more stretchable substrates may be connected to the stretchable device 100. The wire 2 is not limited to the disposition illustrated in FIG. 1, and the extending direction is not limited either. Specifically, a longitudinal direction of the stretchable substrate 1 and the extending direction of the wire 2 do not have to coincide with each other, and the wire does not have to extend in one direction. In addition, the number of the wires 2 is not particularly limited, and it may be one or more.

The term “on” in the present specification does not have to coincide with the upper or lower surface when the stretchable device 100 is used. More specifically, “on a main surface of the stretchable substrate 1” refers to not an absolute direction such as vertically upward defined in the direction of gravity but a direction toward the outside between the outside and the inside with the main surface of the stretchable substrate 1 as a boundary, with the main surface as a reference. Further, “above” with respect to a certain element includes not only an upper position away from the element, that is, an upper position with another object interposed therebetween on the element or an upper position at an interval, but also a position in contact with and immediately above (on) the element.

The stretchable substrate 1 includes a first main surface 1a and a second main surface 1b positioned opposite to each other. The stretchable substrate 1 includes a stretchable substrate end 11 connecting the first main surface 1a and the second main surface 1b. The stretchable substrate 1 has stretchability. Since the stretchable substrate 1 has stretchability, the risk of breakage in stretching at the time of use of the stretchable device 100 can be reduced without suppressing stretching of the wire 2.

In the stretchable substrate 1, the first main surface 1a has an oxygen atomic proportion of 5 at % or more as measured by X-ray photoelectron spectroscopy (XPS). The oxygen atomic proportion is preferably 25 at % or less. With the configuration, the surface of the stretchable substrate is modified. As a result, tackiness and autohesion of the stretchable substrate 1 can be suppressed. Usually, it is considered that tackiness and autohesion of the stretchable substrate 1 are improved by containing oxygen atoms. However, in the present embodiment, it has been found that tackiness and autohesion can be suppressed by containing oxygen atoms. For example, the stretchable substrate 1 can be used for a living body. As a result, handling of the stretchable substrate 1 becomes easy, and the living body (for example, the user) can comfortably use the stretchable substrate 1. In the present embodiment, oxygen atoms are introduced into the first main surface 1a, but the oxygen atoms may be introduced into the second main surface 1b, or may be introduced into the first main surface 1a and the second main surface 1b. The oxygen atomic proportion is a proportion with respect to all the atoms.

Since the X-ray photoelectron spectroscopy has high detection sensitivity on the first main surface 1a, it can be used to obtain the proportion of constituent elements of the first main surface 1a. The proportion of oxygen atoms can be determined through measurement by X-ray photoelectron spectroscopy at a position on the first main surface 1a where the wire 2 is not present. The position may be provided at an end of the stretchable substrate 1 or may be provided between the stretchable substrate 1 and the wire. From the viewpoint of suppressing autohesion properties, it is preferable to provide the position at an end of the stretchable substrate 1. The second main surface 1b may have the same oxygen atomic proportion as that of the first main surface 1a. The proportion of the oxygen concentration of the second main surface 1b can be measured in the same manner as the proportion of the oxygen atoms of the first main surface 1a.

Preferably, the oxygen atomic proportion at a central portion of the first main surface 1a and the second main surface 1b in a direction orthogonal to the first main surface 1a and the second main surface 1b is 5 at % or less, more preferably 1 at % or less. For example, by performing ozone treatment, a portion closer to the first main surface 1a or the second main surface 1b than the central portion is oxidized, and there are more oxygen atoms on the first main surface 1a side or the second main surface 1b side than the central portion. By having such a configuration, tackiness and autohesion of the stretchable substrate 1 can be suppressed. The central portion of the first main surface 1a and the second main surface 1b means an intersection of a central part of the first main surface 1a and the second main surface 1b in a height direction and a central part of the stretchable substrate in a width direction as viewed from a direction orthogonal to the first main surface 1a and the second main surface 1b. The central portion may be substantially the center, and for example, a range separated by +20% from the center of the first main surface 1a and the second main surface 1b may be measured.

The oxygen atomic proportion of the first main surface 1a is 5 at % or more with respect to all the atoms, and it may be higher by 4 at % or more than the oxygen atomic proportion at the central portion of the first main surface 1a and the second main surface 1b in the direction orthogonal to the first main surface 1a and the second main surface 1b. For example, the oxygen atomic proportion at the central portion of the first main surface 1a and the second main surface 1b in the direction orthogonal to the first main surface 1a and the second main surface 1b is 1 at % with respect to all the atoms, and the oxygen atomic proportion of at least either the first main surface 1a or the second main surface 1b is 5 at % or more.

Oxygen atoms can be introduced into the first main surface 1a of the stretchable substrate 1, for example, by performing ozone treatment. The ozone treatment can be performed using, for example, a low-pressure mercury lamp. The ozone treatment can be performed, for example, through exposure for approximately 1 to 3 minutes under ultraviolet (UV) irradiation with the ozone concentration set to about 10 to 120 ppm. The introduction of oxygen atoms can be performed in the same manner in the case of introducing oxygen atoms into the second main surface 1b.

Preferably, it is not necessary to add an inorganic material to the stretchable substrate 1. With such a configuration, permanent strain can be suppressed, and autohesion on the surface can be suppressed. The stretchable substrate 1 can be used as a sensor device.

Examples of the stretchable substrate 1 include a sheet-like, film-like, or block-like base material made of a resin material having stretchability. The resin material is preferably a rubber or an elastomer. The use of the base material allows the surface of the stretchable substrate 1 to be modified, and as a result, tackiness and autohesion of the stretchable substrate 1 can be suppressed.

The resin material is not particularly limited as long as it is a rubber or an elastomer. Examples thereof include an acrylic resin, a styrene-based resin, and a urethane-based resin, and preferably include at least one resin selected from the group consisting of an acrylic resin, a styrene-based resin, and a urethane-based resin.

Examples of the acrylic resin include an acrylic thermoplastic elastomer.

Examples of the styrene-based resin include a styrene-based elastomer.

Examples of the urethane-based resin include thermoplastic polyurethane.

The thickness of the stretchable substrate 1 is not particularly limited, but is preferably 1 mm or less, more preferably 100 μm or less, still more preferably 50 μm or less, from the viewpoint of preventing stretching of a surface of a living body from being impaired when the stretchable substrate 1 is attached to the living body. The thickness of the stretchable substrate 1 is more preferably 1 μm or more.

The wire 2 is provided on the first main surface 1a of the stretchable substrate 1. The wire 2 preferably has stretchability. Examples of a material of the wire 2 include a mixture of metal powder of Ag, Cu, Ni, or the like as conductive particles and elastomer-based resin such as silicone resin. An average particle size of the conductive particles is not particularly limited, but is preferably 0.01 μm to 10 μm. The shape of the conductive particles is preferably spherical. The shape is not limited to spherical, but it may be a flat shape for improving stretchability, or it may have a structure having a protrusion. The elastomer-based resin contains at least one resin (elastomer-based resin) selected from the group consisting of an epoxy-based resin, a urethane-based resin, an acrylic resin, and a silicone-based resin, which is preferable in securing stretchability. Only one wire 2 may be provided on the first main surface 1a of the stretchable substrate 1. Two to three, or five or more wires 2 may be provided.

The thickness of the wire 2 is preferably 100 μm or less, more preferably 50 μm or less. The thickness of the wire 2 is more preferably 1 μm or more, and it may be 5 μm or more. The thickness, width, and length of the wire 2 are not particularly limited. The wire 2 does not have to have stretchability.

### (Production Method)

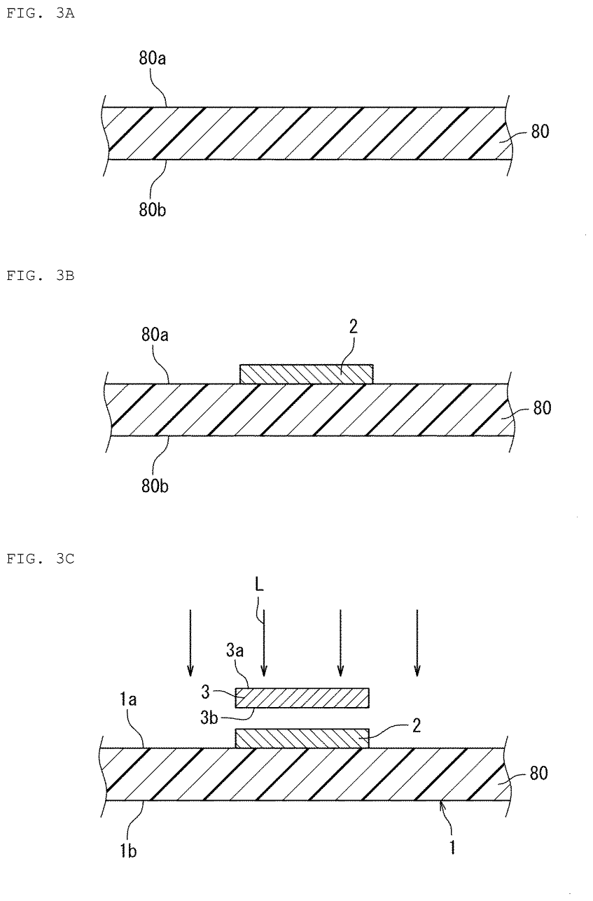

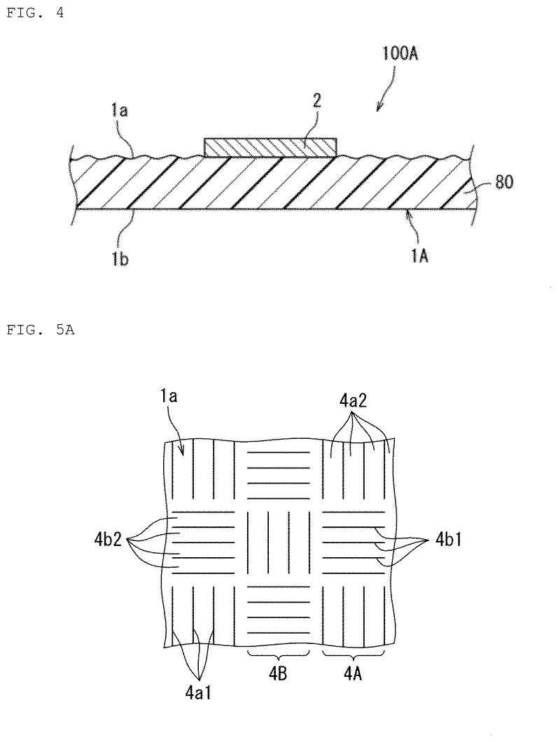

A method for producing the stretchable device 100 will be described with reference to FIGS. 3A, 3B, and 3C.

First, as illustrated in FIG. 3A, prepare a base material 80 having a first surface 80a and a second surface 80b facing opposite of each other (preparation step). As illustrated in FIG. 3B, apply the material of the wire 2 onto the first surface 80a of the base material 80. When the material of the wire 2 is, for example, a conductive paste containing a mixture of Ag and a resin, the conductive paste is applied to the base material. The application method may be screen printing, gravure printing, or inkjet printing. Thereafter, thermally cure the conductive paste to obtain a predetermined resistance value, through which the wire 2 is formed on the base material 80 (disposition step). As illustrated in FIG. 3C, prepare a sheet material 3. The sheet material 3 covers a portion not desired to be subjected to ozone treatment. The sheet material 3 includes a first main surface 3a and a second main surface 3b positioned on the opposite side from the first main surface 3a. As illustrated in FIG. 3C, the second main surface 3b of the sheet material 3 is provided on the upper surface of the wire 2 on the opposite side from the base material 80. Irradiate the first main surface 3a of the sheet material 3 and the first surface 80a of the base material 80 with ozone L (ozone treatment step). That is, the wire 2 is not irradiated with the ozone L. The stretchable device 100 is thus formed. The sheet material 3 is separated from the wire 2 in FIG. 3C, but it may be provided in contact with the wire 2. In the first embodiment, the wire 2 is provided on the base material 80, but the object of the first embodiment may be only the base material 80 without the wire 2. In the first embodiment, one base material 80 is used as the base material 80, but a plurality of base materials 80 may be stacked. Through the steps, the stretchable device 100 in which autohesion is suppressed can be formed. In addition, ozone treatment can be performed in a state where the device has the wire 2, and the production method can be simplified. After the ozone treatment step, an embossing step of pressing an embossing sheet material against the first surface 80a of the base material 80 may be performed.

### (First Modification)

In the stretchable substrate 1, the proportion of oxygen atoms of the first main surface 1a is 5 at % or more. In addition, an arithmetic average surface roughness Ra of the first main surface 1a measured with an atomic force microscope (AFM) is 8 nm or more, and it may be, for example, 10 nm or more. With the configuration, the surface can be roughened, and the tackiness and autohesion of the stretchable substrate 1 can be further suppressed. For example, the autohesion properties can be reduced not only at room temperature but also under more severe conditions (for example, 70° C.). Specifically, the evaluation of the autohesion properties is performed in accordance with JIS K 6404-3:1999 by laying the stretchable substrate 1 over another stretchable substrate 1 in an environment of 70° C. and placing a weight on the superimposed stretchable substrates. In the environment of room temperature as well, similarly to the measurement in the environment of 70° C., measurement is performed by laying the stretchable substrate 1 over another stretchable substrate 1 and placing a weight on the superimposed stretchable substrates. In the present embodiment, the arithmetic average surface roughness Ra of the first main surface 1a is measured, but the second main surface 1b may also have the same arithmetic average surface roughness Ra. The arithmetic average surface roughness Ra may be, for example, 100 nm or less. The measurement with an atomic force microscope may be performed at an end of the stretchable substrate 1 or may be performed at the stretchable substrate 1 positioned between the wires 2. From the viewpoint of suppressing the autohesion properties, the measurement is preferably performed at an end of the stretchable substrate 1. The second main surface 1b of the stretchable substrate 1 may have an arithmetic average surface roughness Ra similar to that of the first main surface 1a.

The first modification can be obtained, for example, by performing heat treatment on the stretchable substrate 1 obtained in the first embodiment. The heat treatment is not particularly limited, but it can be performed at, for example, 150° C. or higher, specifically, 160° C. or higher. The heat treatment can be performed at, for example, 180° C. or lower. The heat treatment time is not particularly limited, but it can be, for example, 10 minutes to 180 minutes, specifically 20 minutes or more, and more specifically 30 minutes or more.

### (Second Modification)

In the stretchable substrate 1, the proportion of oxygen atoms of the surface is 5 at % or more, and the stretchable substrate 1 may further include a first portion and a second portion having different phases measured with an atomic force microscope. The phase of the first portion may be advanced by 10° or more from the phase of the second portion, and the first portion may have a surface occupancy of 80% or more. That is, the first portion of the stretchable substrate 1 may be harder than the second portion, and the surface occupancy of the hard first portion may be 80% or more of the stretchable substrate 1. The surface occupancy may be, for example, 100% or less of the stretchable substrate 1. With the configuration, the surface of the stretchable substrate 1 becomes hard, and the tackiness and autohesion of the stretchable substrate 1 can be further suppressed. For example, the autohesion properties of the stretchable substrate 1 can be reduced not only at room temperature but also under more severe conditions (for example, 70° C.). The “surface occupancy” means the proportion of the area occupied by the portion occupied by the first portion to the measurement area. In the present embodiment, a value obtained by measuring the surface occupancy of the first main surface 1a is used, but the value may be the surface occupancy of the second main surface 1b or the surface occupancy of the first main surface 1a and the second main surface 1b.

The surface occupancy is measured using an atomic force microscope. Specifically, in the region where the wire 2 is not present on the first main surface 1a, a phase image capable of measuring viscoelasticity is obtained with an atomic force microscope, and the surface occupancy of a hard portion whose phase advances by 10° or more is obtained from the phase image.

The region may be provided at an end of the stretchable substrate 1 or may be provided on the stretchable substrate 1 between the wires 2. From the viewpoint of suppressing autohesion, the region is preferable provided at an end of the stretchable substrate 1.

The stretchable substrate 1 of the second modification can be obtained by performing heat treatment on the base material 80 having a proportion of oxygen atoms of 5 at % or more. The heat treatment is not particularly limited, but it can be performed at, for example, 70° C. or higher, specifically, 80° C. or higher. The heat treatment can be performed at, for example, 110° C. or lower, specifically 100° C. or lower. The heat treatment time is not particularly limited, but it can be, for example, 20 minutes to 120 minutes, specifically it can be 30 minutes to 90 minutes.

In the stretchable substrate 1, the proportion of oxygen atoms of the surface measured by X-ray photoelectron spectroscopy may be 5 at % or more, the arithmetic average surface roughness Ra of the surface measured with an atomic force microscope may be 8 nm or more, and the surface occupancy of a hard portion having a phase advanced by 10° or more measured with an atomic force microscope may be 80% or more.

### Second Embodiment

A configuration of a stretchable device 100A according to a second embodiment will be described with reference to FIG. 4. Unlike the first embodiment, the stretchable substrate 1A of the present embodiment has an arithmetic average surface roughness of a specific surface. That is, in the second embodiment, the proportion of oxygen atoms on the surface of the stretchable substrate 1A does not have to be 5 at % or more. Other configurations are the same as those of the first embodiment, and the description thereof will be omitted. The configurations and materials of the stretchable substrate 1A, the first main surface 1a, the second main surface 1b, and the base material 80 may be the same as those of the stretchable substrate 1, the first main surface 1a, the second main surface 1b, and the base material 80 of the first embodiment, respectively, unless described below. The proportion of oxygen atoms of the surface of the stretchable substrate 1A may be 5 at % or more.

As illustrated in FIG. 4, in the stretchable substrate 1A, the surface measured with a laser microscope, that is, the first main surface 1a has an arithmetic average surface roughness Ra′ of 6 μm or more. With the configuration, the surface of the stretchable substrate 1A is modified. As a result, tackiness and autohesion of the stretchable substrate 1A can be suppressed. The arithmetic average surface roughness Ra′ of the first main surface 1a of the stretchable substrate 1A may be, for example, 10 μm or less. The arithmetic average surface roughness Ra′ can be measured in a region on the first main surface 1a where the wire 2 is not present. The region may be provided at an end of the stretchable substrate 1A or may be provided on the stretchable substrate 1A between the wires 2. From the viewpoint of suppressing autohesion, the region is preferable provided at an end of the stretchable substrate 1A. The arithmetic average surface roughness Ra′ is measured using, for example, a non-contact type film pressure measuring device. The arithmetic average surface roughness Ra′ can also be measured with a contact type film pressure measuring device. In the present embodiment, the arithmetic average surface roughness Ra′ of the first main surface 1a of the stretchable substrate 1A is described as 6 μm or more, but it may be, for example, 3 μm or more. In the present embodiment, the arithmetic average surface roughness Ra′ of the first main surface 1a is described. However, not only the arithmetic average surface roughness Ra′ of the first main surface 1a, but also the arithmetic average surface roughness Ra′ of the second main surface 1b may fall within the above range.

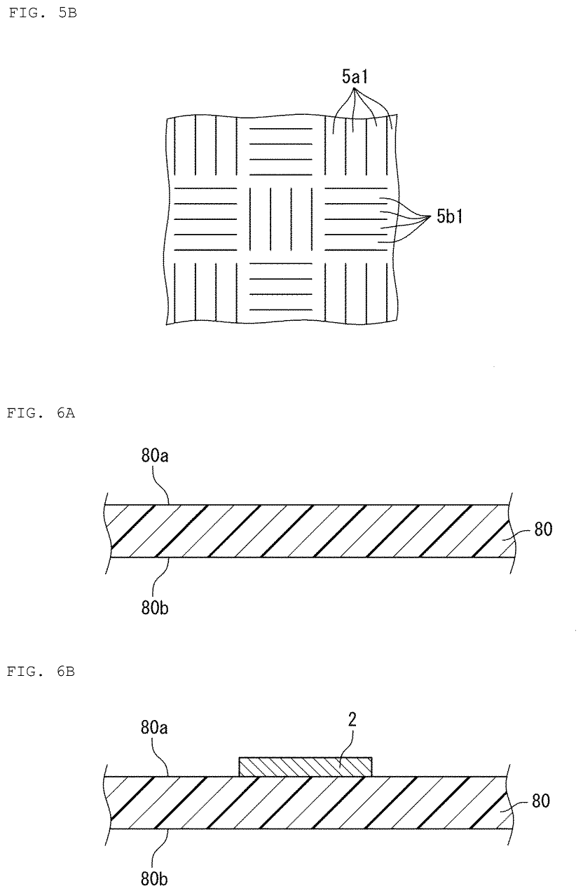

As illustrated in FIG. 5A, the first main surface 1a of the stretchable substrate 1A preferably has a lattice shape. In the lattice shape, a plurality of rectangular first shapes 4A and a plurality of rectangular second shapes 4B are alternately provided in longitudinal and lateral directions. Each rectangle is, for example, 10 to 100 μm square.

The first shape 4A includes a plurality of protrusions 4a1 and a plurality of recessed grooves 4a2. The recessed grooves 4a2 extend in a lateral direction. The recessed grooves 4a2 are arranged in parallel in the lateral direction. The protrusions 4a1 are positioned between adjacent recessed grooves 4a2. By performing the steps described above, unevenness can be formed on the surface of the stretchable substrate 1A. That is, the surface roughness can be increased by performing the steps. In addition, the surface of the stretchable substrate 1A can be hardened. As a result, the autohesion of the stretchable substrate 1A can be further suppressed.

The second shape 4B includes a plurality of protrusions 4b1 and a plurality of recessed grooves 4b2. The recessed grooves 4b2 extend in a lateral direction. The recessed grooves 4b2 are arranged in parallel in the lateral direction. The protrusions 4b1 are positioned between adjacent recessed grooves 4b2. With the configuration, a member is less likely to come into contact with the first main surface 1a, and the tackiness and autohesion of the stretchable substrate 1A can be suppressed. The lattice shape may be provided only on a part of the first main surface 1a. The lattice shape may be provided not only on the first main surface 1a but also on the second main surface 1b.

As illustrated in FIG. 5B, the lattice shape is formed on the first main surface 1a by performing embossing using an embossing sheet material 5. In the embossing sheet material 5, warp yarn portions 5a1 and weft yarn portions 5b1 are alternately interwoven. The embossing includes a heat and pressure treatment step of performing heat treatment and pressure treatment.

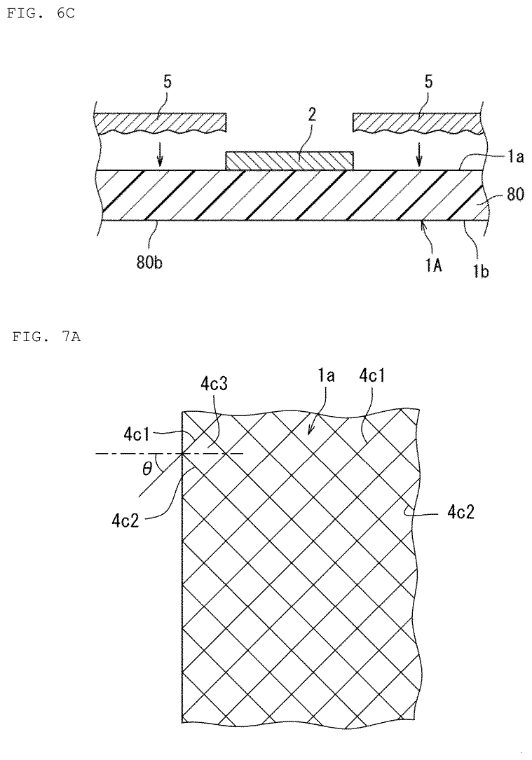

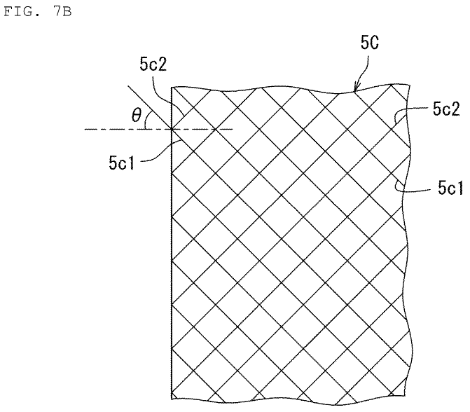

A method for producing the stretchable device 100A will be described with reference to FIGS. 6A, 6B, and 6C.

First, as illustrated in FIG. 6A, prepare the base material 80 (preparation step). As illustrated in FIG. 6B, apply the material of the wire 2 onto the first surface 80a of the base material 80 (disposition step). As illustrated in FIG. 6C, provide the embossing sheet material 5 having a surface pattern on the upper surface of the wire 2 on the opposite side from the base material 80. The embossing sheet material 5 is not in contact with the wire 2. Press the embossing sheet material 5 against the first surface 80a of the base material 80. As a result, the shape of the embossing sheet material 5 is transferred to the first surface 80a, and the first main surface 1a is formed (embossing step). The embossing sheet material 5 may cover only a part of a region other than the wire 2 on the first surface 80a. By performing the steps, autohesion on the surface of the stretchable device 100A can be suppressed. In addition, embossing can be performed in a state where the device has the wire 2, and the production method can be simplified.

In the present embodiment, the embossing sheet material 5 is provided so as not to overlap with the wire 2, but in another embodiment, a protective layer for protecting the wire 2 may be provided, and the embossing sheet material 5 may be pressed against the base material 80 and the protective layer. Embossing may be performed on the surface of the base material 80 opposite to the wire 2.

### (First Modification)

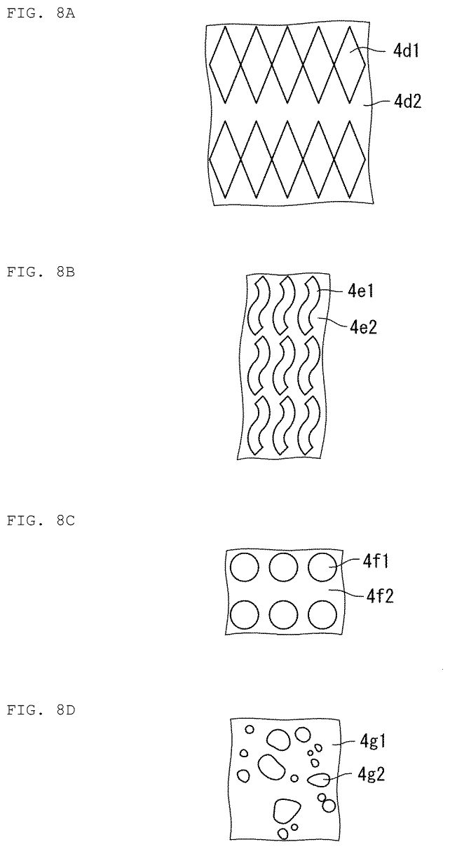

The first main surface 1a of the stretchable substrate 1A has a shape illustrated in FIG. 7A instead of the lattice shape illustrated in FIG. 5A.

As illustrated in FIG. 7A, the first main surface 1a includes a plurality of first recesses 4cl and a plurality of second recesses 4c2 orthogonal to the first recesses 4cl. An angle θ between an extending direction of the first recess 4cl and an orthogonal line D orthogonal to a longitudinal direction of the stretchable substrate 1A is approximately 45°. An angle between an extending direction of the second recess 4c2 and the orthogonal line D orthogonal to the longitudinal direction of the stretchable substrate 1A is approximately −45°. One first recess 4cl, another first recess 4cl adjacent to the first recess 4cl, one second recess 4c2, and another second recess 4c2 adjacent to the second recess 4c2 form a rectangle 4c3. The shape may be provided only on a part of the first main surface 1a. The shape of the first modification may be provided not only on the first main surface 1a but also on the second main surface 1b. The intersection angle between the first recess 4cl and the second recess 4c2 does not have to be 90°, but it may be approximately 90°. The angle θ is not limited to the value described above, but it may be, for example, 00, 15°, or 30°. That is, the angle θ may take any value between 0° and 90°.

The distance between adjacent first recesses 4cl is, for example, 1 to 10 μm. The distance between adjacent second recesses 4c2 is, for example, 1 to 10 μm.

As illustrated in FIG. 7B, the shape of the first modification is formed on the first main surface 1a by performing embossing using an embossing sheet material 5C. The embossing sheet material 5C includes a first protrusion 5cl, a second protrusion 5c2, and a recess surrounded by the first protrusion 5cl and the second protrusion 5c2.

The embossing may be performed using a sheet material that forms a recess and a protrusion on the first main surface 1a of the stretchable substrate 1A. The recess and the protrusion may be provided in a pattern shape or may be provided in a random shape. The protrusions may have different sizes and shapes, and the recesses may have different sizes and shapes. For example, as illustrated in FIG. 8A, the embossing sheet material 5 may be a sheet material that provides a rhombic protrusion 4dl and a remaining partial recess 4d2 on the first main surface 1a. As illustrated in FIG. 8B, the embossing sheet material 5 may be a sheet material that provides a wave-shaped protrusion 4e1 and a remaining partial recess 4e2 on the first main surface 1a. As illustrated in FIG. 8C, the embossing sheet material may be a sheet material that provides a circular shape 4f1 and a remaining portion 4f2 on the first main surface 1a. As illustrated in FIG. 8D, the embossing sheet material may be a sheet material that provides a mesh-like protrusion 4g1 and a remaining partial recess 4g2 on the first main surface 1a.

### Third Embodiment

A structure of a stretchable device 100B according to a third embodiment will be described with reference to FIG. 9. FIG. 9 is a sectional view of the stretchable device 100B, corresponding to FIG. 2. The third embodiment is different from the first embodiment in the treatment method performed on the stretchable substrate. This different configuration will be described below. Other configurations are the same as those of the first embodiment, and the description thereof will be omitted. The configurations and materials of the stretchable substrate 1B, the first main surface 1a, the second main surface 1b, and the base material 80 may be the same as those of the stretchable substrate 1, the first main surface 1a, the second main surface 1b, and the base material 80 of the first embodiment, respectively, unless described below.

As illustrated in FIG. 9, the stretchable device 100B includes a stretchable substrate 1B including the first main surface 1a and the second main surface 1b facing opposite of each other, and the wire 2 provided on the first main surface 1a. In the third embodiment, the first surface 80a of the base material 80 is the same as the first main surface 1a of the stretchable substrate 1B. The surface of a metal-containing portion 81 on the opposite side from the second surface 80b is the second main surface 1b of the stretchable substrate 1B. By having the metal-containing portion 81, molecular diffusion causing autohesion in the base material 80 is suppressed, and autohesion between the stretchable substrates 1B can be suppressed. Here, the metal-containing portion 81 means a portion containing a metal-containing compound. Examples of the metal-containing compound include a metal and a metal oxide.

The metal-containing portion 81 may contain a plurality of metal atoms or one type of metal atom. In the third embodiment, the metal-containing portion 81 is positioned on the second main surface 1b side, but the metal-containing portion 81 may be positioned on the first main surface 1a side, or the metal-containing portion 81 may be positioned on the first main surface 1a side and the second main surface 1b side. The stretchable substrate 1B may include the base material 80 including the metal-containing portion 81, the wire 2 positioned on the opposite side from the metal-containing portion 81 of the base material 80, and another base material 80 positioned on the wire 2. The stretchable substrate 1B may include the metal-containing portion 81 on a surface of another base material 80 on the opposite side from the wire 2. The base material 80 may be composed of only one layer, or a plurality of layers may be stacked. The stretchable substrate 1B may be composed of only one layer, or a plurality of layers may be stacked.

Preferably, on the second main surface 1b, the constituent proportion of metal in the metal-containing portion 81 measured by X-ray photoelectron spectroscopy is 0.5 at % or more. The upper limit value of the constituent proportion of metal in the metal-containing portion 81 is not particularly limited, but it may be, for example, 3 at % or less. With the configuration, metal atoms can be uniformly dispersed. This can prevent the stretchable substrate 1B from becoming hard. In addition, coloring derived from the metal atoms can be dispersed by uniformly dispersing the metal atoms. When the proportion of metal elements is too high, the safety of the stretchable substrate 1B degrades. When the proportion of metal elements is too low, molecular diffusion in the base material 80 cannot be suppressed, and for example, autohesion occurs between the stretchable substrates 1B.

Preferably, the metal-containing portion 81 contains at least one selected from the group consisting of Al, Fe, Ni, Au, Pt, Ag, and Ti. With the configuration, molecular diffusion causing autohesion in the base material 80 is suppressed, and autohesion between the stretchable substrates 1B can be further suppressed.

Preferably, the metal-containing portion 81 contains Al. The configuration is preferable from the viewpoint of biocompatibility. In particular, it is considered that Al is stably present as an oxide, which is preferable from the viewpoint of improving the safety of the stretchable substrate 1B. The configuration is also preferable from the viewpoint of cost. Al may be present as a metal instead of an oxide.

Preferably, the metal-containing portion 81 contains at least either a metal or a metal oxide. With the configuration, the metal-containing portion 81 can be stably present on the base material 80. The metal-containing portion 81 may contain a plurality of metal atoms or may contain only a single metal atom.

Preferably, the stretchable substrate 1B further includes a protective layer that protects the wire 2. The protective layer is provided in the same layer as the wire 2 or so as to cover the wire 2. With the configuration, the wire 2 can be protected. The protective layer may be a single layer, or a plurality of layers may be stacked. The protective layer may be the base material 80.

Preferably, the protective layer covers the wire 2, and the surface of the protective layer positioned on the opposite side from the wire 2 has the metal-containing portion 81.

### (Production Method)

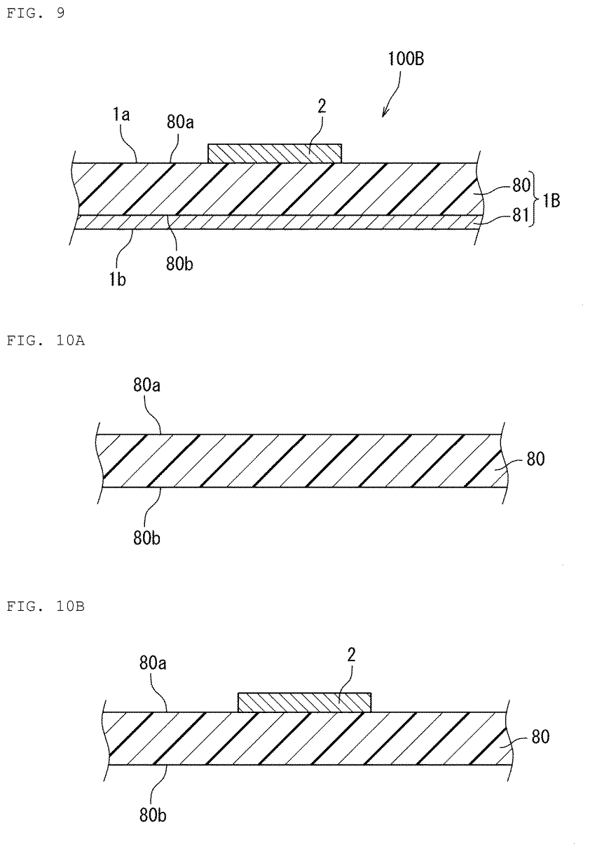

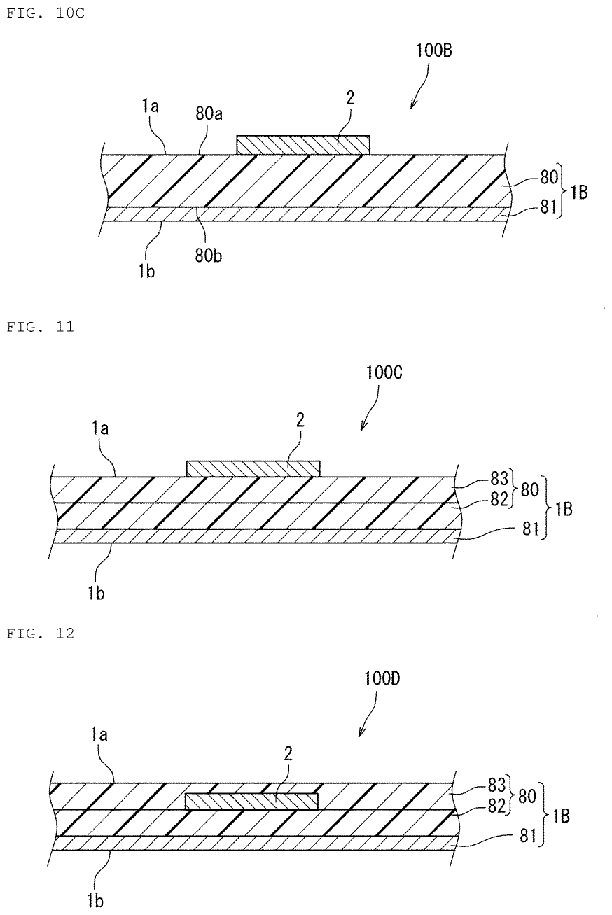

A method for producing the stretchable device 100B will be described with reference to FIGS. 10A, 10B, and 10 C.

First, as illustrated in FIG. 10A, prepare the base material 80 (preparation step). As illustrated in FIG. 10B, form the material of the wire 2 on the first surface 80a of the base material 80 (disposition step). As illustrated in FIG. 10C, form the metal-containing portion 81 on the second surface 80b by a sputtering treatment method (formation step). The sputtering treatment method can be performed using, for example, SV-200 manufactured by ULVAC. For the formation of the metal-containing portion 81, not only a sputtering treatment method but also a thin film formation method such as a vapor deposition method or a chemical vapor deposition (CVD) method may be used. The stretchable device 100B is thus formed. In the preparation step, two base materials 80 may be prepared, and in the disposition step, the material of the wire 2 may be formed on the first surface 80a of one base material 80, and the other base material 80 may be formed on the wire 2.

### (First Modification)

As illustrated in FIG. 11, in the stretchable device 100C, the base material 80 is formed of a base material 82 and a base material 83. Specifically, the stretchable device 100C includes the original stretchable base material 82 so as to cover the metal-containing portion 81, includes the base material 83 on the side of the base material 82 opposite from the metal-containing portion 81, and includes the wire 2 on the side of the base material 83 opposite from the base material 82. The surface of the base material 83 on which the wire 2 is positioned is the first main surface 1a of the stretchable substrate 1B. The base material 80 may be formed of three or more layers. Reference numerals that are not particularly described have the same configurations as those of the third embodiment, and description thereof will be omitted.

### (Second Modification)

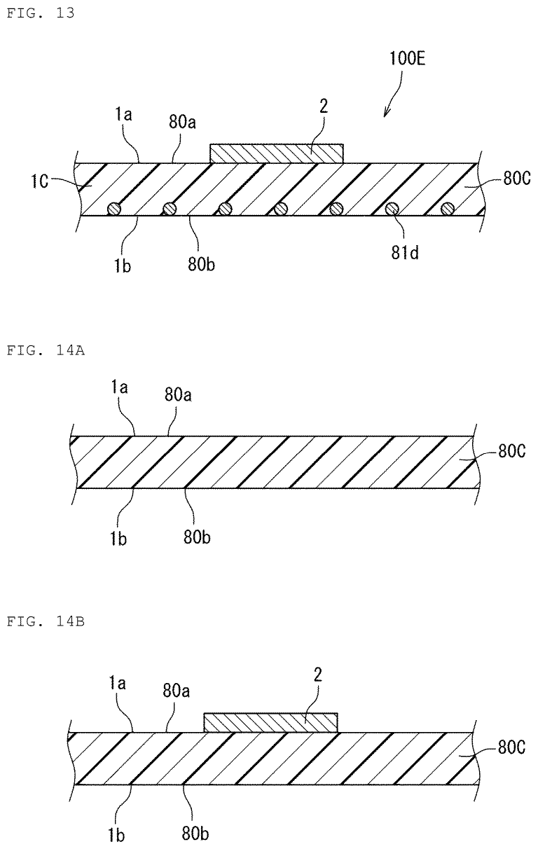

As illustrated in FIG. 12, in a stretchable device 100D, the base material 80 is formed of the base material 82 and the base material 83, and the wire 2 is sandwiched between the base material 82 and the base material 83. Specifically, the stretchable device 100C includes the base material 82, includes the wire 2 on the base material 82, and includes the base material 83 so as to cover the wire 2. The surface of the base material 83 on the opposite side from the wire 2 is the first main surface 1a of the stretchable substrate 1B. The base material 82 has the metal-containing portion 81 on the opposite side from the wire 2. The base material 82 may be formed of two or more layers. The base material 83 may be formed of two or more layers. In the second modification, the metal-containing portion 81 is positioned on the surface of the base material 82 opposite from the wire 2, but it may be positioned on the surface of the base material 83 opposite from the wire 2, or may be positioned on the surface of the base material 82 opposite from the wire 2 and the surface of the base material 83 opposite to the wire 2. Reference numerals that are not particularly described have the same configurations as those of the third embodiment, and description thereof will be omitted.

### Fourth Embodiment

A configuration of a stretchable device 100E according to a fourth embodiment will be described with reference to FIG. 13. FIG. 13 is a sectional view of the stretchable device 100E, corresponding to FIG. 9. In the fourth embodiment, the metal-containing portion 81 of the third embodiment is not provided, but a metal-containing region 81d is provided in a base material 80C. This different configuration will be described below. Other configurations are the same as those of the third embodiment, and the description thereof will be omitted. The configurations and materials of the stretchable substrate 1C, the first main surface 1a, and the second main surface 1b may be the same as those of the stretchable substrate 1, the first main surface 1a, and the second main surface 1b of the first embodiment, respectively, unless described below. The configuration and material of the base material 80C may be the same as those of the base material 80 of the first embodiment except for the metal-containing region 81d.

As illustrated in FIG. 13, the stretchable device 100E includes a stretchable substrate 1C including the first main surface 1a and the second main surface 1b facing opposite of each other, and the wire 2 provided on the first main surface 1a. In the fourth embodiment, the first surface 80a of the base material 80C is the same as the first main surface 1a of the stretchable substrate 1C. The second surface 80b of the base material 80C is the second main surface 1b of the stretchable substrate 1C. In the second surface 80b of the base material 80C, the metal-containing region 81d is positioned along the second surface 80b (second main surface 1b). The metal-containing region 81d is present in the stretchable substrate 1C. With the configuration, molecular diffusion causing autohesion in the base material 80C is suppressed, and autohesion of the stretchable substrate 1C can be suppressed. Further, when the metal-containing region 81d adheres to another printed circuit other than the stretchable substrate 1C, close contact between the metal-containing region 81d and another base material improves, and the close contact force between the stretchable substrate 1C and another base material improves. Further, because the stretchable substrate 1C has the metal-containing region 81d, the stretchable substrate 1C can be brought into close contact with another base material even at a low press temperature. Thus, even at a low temperature, for example, it is possible to perform an attachment treatment to another base material, and the load to be applied to the base material 80C and the wire 2 through heat treatment is reduced. The metal-containing region 81d may be at a position separated from the second main surface 1b of the stretchable substrate 1C.

Preferably, the proportion of metal atoms contained in the metal-containing region 81d in the second main surface 1b of the stretchable substrate 1C is 0.2 at % to 2.5 at %. Here, the proportion in the second main surface 1b refers to a proportion of presence of metal atoms with respect to all the atoms in the second main surface 1b. The proportion of metal atoms can be measured using X-ray photoelectron spectroscopy.

Preferably, the metal-containing regions 81d are interspersed in the second surface 80b of the base material 80C. Specifically, a material constituting the base material 80C, for example, a resin material having stretchability is present between the metal-containing regions 81d. That is, the metal-containing region 81d does not have a layer shape.

Preferably, the metal-containing region 81d is a metal or a metal oxide. With the configuration, the metal-containing region 81d is present safely. The metal-containing region 81d may contain a plurality of metal atoms or may contain only a single metal atom.

Preferably, the metal-containing region 81d more preferably contains a metal oxide.

Preferably, the metal-containing region 81d contains at least one selected from the group consisting of Al, Fe, Ni, Au, Pt, Ag, and Ti. With the configuration, molecular diffusion causing autohesion in the base material 80C is suppressed, and autohesion between the stretchable substrate 1C can be further suppressed.

Preferably, the metal-containing region 81d contains Al. The configuration is preferable from the viewpoint of biocompatibility. In particular, it is considered that Al is stably present as an oxide, which is preferable from the viewpoint of improving the safety of the stretchable substrate 1C. The configuration is also preferable from the viewpoint of cost. Al may be present as a metal.

In the fourth embodiment, the metal-containing region 81d is positioned in the second main surface 1b, but the metal-containing region 81d may be positioned in the first main surface 1a, or the metal-containing region 81d may be positioned in the first main surface 1a and the second main surface 1b. In this case, the proportion in the first main surface 1a refers to the proportion of presence in the same manner as the proportion in the second main surface 1b. The proportion of metal atoms is a proportion with respect to all the atoms.

### (Production Method)

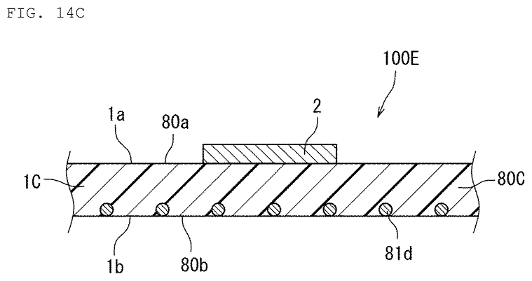

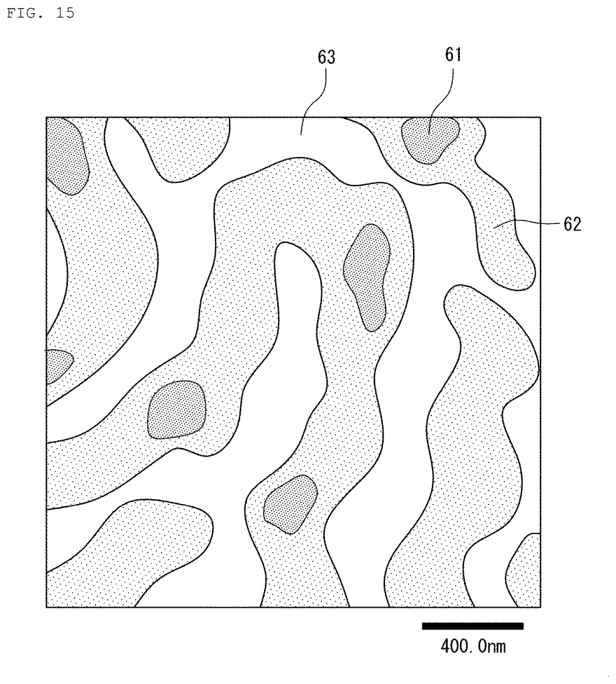

A method for producing the stretchable device 100E will be described with reference to FIGS. 14A, 14B, and 14C.

As illustrated in FIG. 14A, prepare the base material 80C having the first main surface 1a and the second main surface 1b facing opposite of each other. As illustrated in FIG. 14B, provide the wire 2 on the first main surface 1a of the base material 80C. As illustrated in FIG. 14C, provide the metal-containing region 81d in the base material 80C. The stretchable device 100E is thus formed.

### EXAMPLES

The present disclosure will be described in more detail below with reference to Examples, but the present disclosure is not limited only to these Examples.

### First Example

### Example 1

Two styrene-based elastomer films were prepared. These styrene-based elastomer films were subjected to ozone treatment by the following method.

### [Ozone Treatment]

The ozone treatment was performed using SKB2003N manufactured by Sun Energy Corporation that generates ozone with a low-pressure mercury lamp.

The proportion of oxygen atoms of the surface of the base material after the ozone treatment was measured as follows.

### [Measurement of Proportion of Oxygen Atom of Surface of Base Material]

The proportion of oxygen atoms of the outermost surface of the base material was measured using the following device.

Device: X-ray photoelectron spectroscopy (XPS, Quantes manufactured by ULVAC-PHI, Inc.)

Acceleration voltage: 15 kV

Measurement region: 1000 μm×200 μm

After the ozone treatment, the surfaces subjected to the ozone treatment were superimposed on each other, and the following autohesion test was performed.

### [Autohesion Test]

Measured at 70° C.

The test was performed in accordance with JIS K 6404-3:1999 (test methods for rubber-coated cloth and plastic-coated cloth). Specifically, in the blocking test, two glass plates having a length of about 150 mm, a width of about 150 mm, and a thickness of 3 mm were prepared, and two prepared films in a state of being superimposed were sandwiched between the glass plates. A weight having a mass of 5.0 kg was placed on the glass plates and allowed to stand in an environment of 70° C. for 3 hours. Thereafter, whether the two test pieces were peeled off was examined.

As the test piece, a film obtained in Examples or Comparative Examples was used.

Adhesive: The test pieces cannot be peeled off.

Slightly adhesive: The films can be peeled off by applying a force.

Non-adhesive: The films do not adhere.

### (2) Measured at Room Temperature

Measurement and evaluation were performed in the same manner as in the measurement at 70° C. except that the measurement temperature was room temperature.

### Examples 2 to 6

Two styrene-based elastomer films were prepared in the same manner as in Example 1. These styrene-based elastomer films were subjected to ozone treatment. The proportion of oxygen atoms of the surface of the base material after the ozone treatment was performed in the same manner as in Example 1.

After the ozone treatment, the surfaces subjected to the ozone treatment were superimposed on each other, and an autohesion test was performed in the same manner as in Example 1.

### Comparative Example 1

Two styrene-based elastomer films were prepared in the same manner as in Example 1. The proportion of oxygen atoms on the surface of the base material was the same as in Example 1.

Two styrene-based elastomer films were superimposed on each other, and an autohesion test was performed in the same manner as in Example 1.

### Comparative Example 2

Two styrene-based elastomer films were prepared in the same manner as in Example 1. These styrene-based elastomer films were subjected to ozone treatment. The proportion of oxygen atoms of the surface of the base material after the ozone treatment was performed in the same manner as in Example 1.

After the ozone treatment, the surfaces subjected to the ozone treatment were superimposed on each other, and an autohesion test was performed in the same manner as in Example 1.

The results are shown in Table 1.

TABLE 1

| | Ozone | Proportion | Test results | |
|---|---|---|---|---|
| | treatment | of oxygen | Room | |
| Test No. | time [sec] | atoms [at %] | temperature | 70° C. |
| Comparative | 0 | 1.4 | Adhesive | Adhesive |
| Example 1 | | | | |
| Comparative | 10 | 2.3 | Slightly | Adhesive |
| Example 2 | | | adhesive | |
| Example 1 | 30 | 5.1 | Non- | Slightly |
| | | | adhesive | adhesive |
| Example 2 | 60 | 7.6 | Non- | Slightly |
| | | | adhesive | adhesive |
| Example 3 | 120 | 12.9 | Non- | Slightly |
| | | | adhesive | adhesive |
| Example 4 | 180 | 17.0 | Non- | Slightly |
| | | | adhesive | adhesive |
| Example 5 | 300 | 20.2 | Non- | Slightly |
| | | | adhesive | adhesive |
| Example 6 | 600 | 19.6 | Non- | Slightly |
| | | | adhesive | adhesive |

As shown in Table 1, in Comparative Example 1, ozone treatment was not performed, and the proportion of oxygen atoms was 1.4 at %. That is, the styrene-based elastomer film contained almost no oxygen atoms before the ozone treatment. In Comparative Example 1, the films were adhered at room temperature. In Comparative Example 2, the proportion of oxygen atoms was 2.3 at %, but the films were slightly adhesive at room temperature, and were adhered under more severe conditions (70° C.). Examples 1 to 6 further contained oxygen atoms, were not adhered at room temperature, and were slightly adhered even under more severe conditions (70° C.).

In the above Examples, oxygen atoms equal to or more than the values shown in Table 1 were not able to be added.

### Second Example

### Example 7

Two urethane-based elastomer films were prepared. These styrene-based elastomer films were subjected to ozone treatment using the same method as in Example 1. The proportion of oxygen atoms of the surface of the base material after the ozone treatment was measured in the same manner as in Example 1.

After the ozone treatment, the surfaces subjected to the ozone treatment were superimposed on each other, and an autohesion test was performed in the same manner as in Example 1.

### Examples 8 to 12

Two urethane-based elastomer films were prepared in the same manner as in Example 7. These urethane-based elastomer films were subjected to ozone treatment. The proportion of oxygen atoms of the surface of the base material after the ozone treatment was performed in the same manner as in Example 1.

After the ozone treatment, the surfaces subjected to the ozone treatment were superimposed on each other, and an autohesion test was performed in the same manner as in Example 1.

### Comparative Example 3

Two urethane-based elastomer films were prepared in the same manner as in Example 7. The proportion of oxygen atoms on the surface of the base material was the same as in Example 1.

Two styrene-based elastomer films were superimposed on each other, and an autohesion test was performed in the same manner as in Example 1.

### Comparative Example 4

Two urethane-based elastomer films were prepared in the same manner as in Example 7. These urethane-based elastomer films were subjected to ozone treatment. The proportion of oxygen atoms of the surface of the base material after the ozone treatment was performed in the same manner as in Example 1.

After the ozone treatment, the surfaces subjected to the ozone treatment were superimposed on each other, and an autohesion test was performed in the same manner as in Example 1.

The results are shown in Table 2.

TABLE 2

| | Ozone | Proportion of | Test results | |
|---|---|---|---|---|
| | treatment | oxygen atoms | Room | |
| Test No. | time [sec] | [at %] | temperature | 70° C. |
| Comparative | 0 | 3.8 | Adhesive | Adhesive |
| Example 3 | | | | |
| Comparative | 10 | 4.9 | Slightly | Adhesive |
| Example 4 | | | adhesive | |
| Example 7 | 30 | 8.7 | Non- | Non- |
| | | | adhesive | adhesive |
| Example 8 | 60 | 11.8 | Non- | Non- |
| | | | adhesive | adhesive |
| Example 9 | 120 | 19.3 | Non- | Non- |
| | | | adhesive | adhesive |
| Example 10 | 180 | 22.1 | Non- | Non- |
| | | | adhesive | adhesive |
| Example 11 | 300 | 24.5 | Non- | Non- |
| | | | adhesive | adhesive |
| Example 12 | 600 | 24.0 | Non- | Non- |
| | | | adhesive | adhesive |

As shown in Table 2, when the proportion of oxygen atoms was low (Comparative Examples 3 and 4), the films were adhered at room temperature and 70° C. It was found that by increasing the proportion of oxygen atoms (Examples 7 to 12), a non-adhesive surface can be formed at room temperature and 70° C.

### Third Example

### Example 13

Two styrene-based elastomer films that are same as those in Example 4 were prepared. These styrene-based elastomer films were subjected to ozone treatment. The arithmetic average surface roughness Ra of the ozone-treated main surface was measured.

### <Measurement of Arithmetic Average Surface Roughness Ra>

Atomic force microscope: atomic force microscope (AFM, manufactured by Bruker Corporation)

Measurement region: 2 μm×2 μm

Measurement interval: 256 μm×256 μm

The surfaces subjected to the ozone treatment were superposed on each other and heat-treated at 160° C. for 10 minutes.

### Examples 14 to 17

Two styrene-based elastomer films were prepared in the same manner as in Example 4. These styrene-based elastomer films were subjected to ozone treatment. The arithmetic average surface roughness Ra of the ozone-treated main surface was measured in the same manner as in Example 13. The surfaces subjected to the ozone treatment were superposed on each other and heat-treated as shown in Table 3.

The results are shown in Table 3. For comparison, Table 3 also shows Example 4 in which heat treatment was not performed.

TABLE 3

| | Ozone | Heat treatment | | | Test results | |
|---|---|---|---|---|---|---|
| | treatment | Temperature | Time | | Room | |
| Test No. | time [sec] | [° C.] | [min] | Ra [nm] | temperature | 70° C. |
| Example 4 | 180 | None | 0 | 1.45 | Non-adhesive | Slightly adhesive |
| Example 13 | 180 | 160 | 10 | 3.54 | Non-adhesive | Slightly adhesive |
| Example 14 | 180 | 160 | 30 | 9.76 | Non-adhesive | Non-adhesive |
| Example 15 | 180 | 160 | 60 | 11.67 | Non-adhesive | Non-adhesive |
| Example 16 | 180 | 160 | 120 | 9.53 | Non-adhesive | Non-adhesive |
| Example 17 | 180 | 160 | 180 | 10.8 | Non-adhesive | Non-adhesive |

As shown in Table 3, in Example 4 (without heat treatment), the films were non-adhesive at room temperature, but slightly adhesive under more severe conditions (70° C.). In Examples 14 to 17, the films were non-adhesive not only at room temperature but also at 70° C. In Examples 14 to 17, the arithmetic average surface roughness Ra is large, and it is considered that a non-adhesive surface can be formed at room temperature and 70° C. by having such a surface.

This will be specifically described with reference to FIG. 15. FIG. 15 is an explanatory view for describing the surface roughness of the stretchable base material. FIG. 15 is a drawing based on a photograph in which the surface roughness of the base material of Example 15 is measured using an atomic force microscope. In FIG. 15, the hardness of the surface increases in the order of a white portion 61, a coarse dot portion 62, and a fine dot portion 63. It has been found that by performing the heat treatment at 160° C., the dot portion 62 and the dot portion 63 increase, and the surface of the base material can be roughened.

In Examples 13 to 17, the proportion of oxygen atoms is considered to be 5 at % or more.

### Fourth Example

### Example 18

Two styrene-based elastomer films were prepared in the same manner as in Example 4. These styrene-based elastomer films were subjected to ozone treatment. The film after the ozone treatment was divided into a first portion and a second portion having different phases as measured by an electron force microscope, and the surface occupancy of a hard portion having no phase delay as the first portion was measured.

### <Measurement of Surface Occupancy>

Device: Atomic force microscope (AFM, manufactured by Bruker Corporation)

Measurement region: 2,000 μm×2,000 μm

Thereafter, the surfaces subjected to the ozone treatment were superimposed on each other, and heat treatment was performed. After the heat treatment, an autohesion test was performed in the same manner as in Example 1.

### Examples 19 to 22

Two styrene-based elastomer films were prepared in the same manner as in Example 18. These styrene-based elastomer films were subjected to ozone treatment. The film after the ozone treatment was divided into a first portion and a second portion having different phases as measured with an electron force microscope, and the surface occupancy of a hard portion having no phase delay as the first portion was measured in the same manner as in Example 18.

The results are shown in Table 4. For comparison, Table 4 also shows Example 4 in which heat treatment was not performed.

TABLE 4

| | Ozone | Heat treatment | | Surface | Test results | |
|---|---|---|---|---|---|---|
| | treatment | Temperature | Time | occupancy | Room | |
| Test No. | time [sec] | [° C.] | [min] | [%] | temperature | 70° C. |
| Example 4 | 180 | None | 0 | 63 | Non-adhesive | Slightly adhesive |
| Example 18 | 180 | 80 | 30 | 82 | Non-adhesive | Non-adhesive |
| Example 19 | 180 | 80 | 60 | 92 | Non-adhesive | Non-adhesive |
| Example 20 | 180 | 100 | 30 | 85 | Non-adhesive | Non-adhesive |
| Example 21 | 180 | 100 | 60 | 91 | Non-adhesive | Non-adhesive |
| Example 22 | 180 | 100 | 90 | 96 | Non-adhesive | Non-adhesive |

As shown in Table 4, in Example 4 in which only the ozone treatment was performed, the films were non-adhesive at room temperature, but slightly adhesive at 70° C. On the other hand, in Examples 18 to 22 in which heat treatment was performed after ozone treatment, the films were non-adhesive at room temperature and 70° C. In Examples 18 to 22, it is considered that the surface occupancy was increased by performing the heat treatment, and as a result, the films became non-adhesive not only at room temperature but also at 70° C.

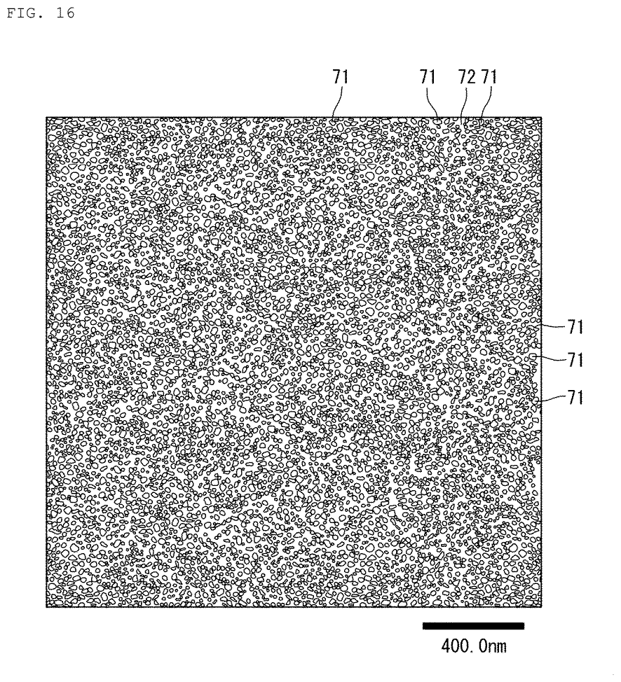

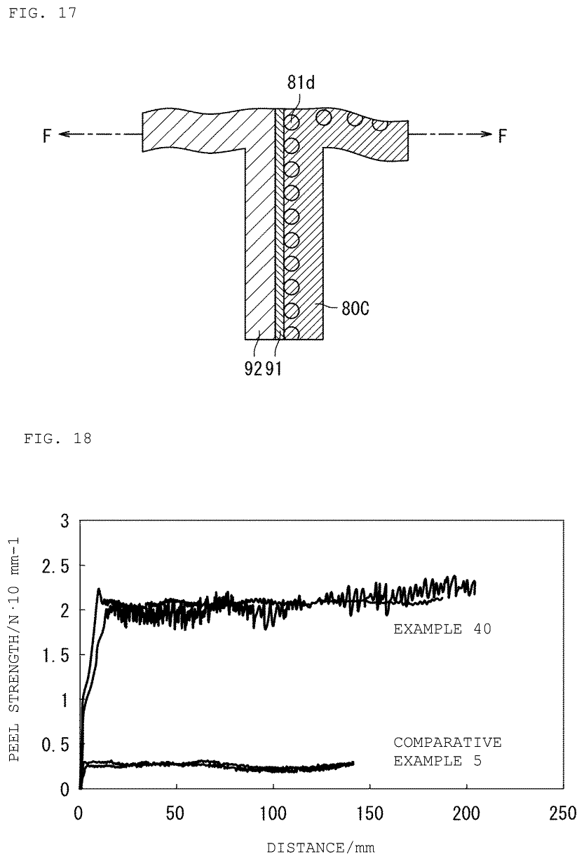

This will be specifically described with reference to FIG. 16. In FIG. 16, there are a first portion 71 and a second portion 72 illustrated in a particulate form. As illustrated in FIG. 16, it was found that the proportion of the first portion 71 was increased by performing the heat treatment.

### Fifth Example

### Reference Example 23

Two urethane-based elastomer films were prepared in the same manner as in Comparative Example 3. These urethane-based elastomer films were superposed on each other, and embossing was performed by pressing an embossing film.

### <Embossing Film>

The embossing film had a lattice shape, and had a rectangular first shape 4A having a recessed groove in a longitudinal direction and a rectangular second shape 4B having a recessed groove in a lateral direction. Each rectangle was 25 μm square. Each of the first shape 5A and the second shape 4B had 3 to 10 recessed grooves.

After embossing, the arithmetic average surface roughness Ra′ of the surface was measured using a laser microscope.

### <Measurement of Arithmetic Average Surface Roughness Ra′>

Laser microscope: VK-9500 (manufactured by KEYENCE CORPORATION)

Measurement method: laser type non-contact

Measurement region: 1,012 μm×1,350 μm

### Examples 24 and 25

Two urethane-based elastomer films were prepared in the same manner as in Reference Example 23. These urethane-based elastomer films were superposed on each other, and using the same embossing film as in Reference Example 23, they were pressure-pressed under the following conditions. The depth of the pressure pressing was larger than that in Reference Example 23.

### <Pressure Pressing>

Hot pressing was performed for 1 minute in a state where the films were heated to 70° C.

The arithmetic average surface roughness Ra′ of the surface after embossing was measured in the same manner as in Reference Example 23.

The results are shown in Table 5.

TABLE 5

| | | Test results | |
|---|---|---|---|
| Test No. | Ra′ [μm] | Room temperature | 70° C. |
| Comparative | 0.3 | Adhesive | Adhesive |
| Example 3 | | | |
| Reference | 3.4 | Non-adhesive | Adhesive |
| Example 23 | | | |
| Example 24 | 6.1 | Non-adhesive | Non-adhesive |
| Example 25 | 6.8 | Non-adhesive | Non-adhesive |

As shown in Table 5, in Comparative Example 3, embossing was not performed, and the films were adhered at room temperature. In Reference Example 23, the films were non-adhesive at room temperature. In Examples 24 and 25, the films were non-adhesive at room temperature and 70° C. This is considered to be because the arithmetic average surface roughness Ra′ was larger, the area of the top of the protrusion was smaller, and the contact area was reduced after embossing (Reference Example 23, Examples 24 and 25) than before embossing (Comparative Example 3).

### Sixth Example

### Examples 26 to 29

Two styrene-based elastomer films were prepared. These styrene-based elastomer films were subjected to a sputtering treatment using Al metal using SV-200 manufactured by ULVAC, Inc. In X-ray photoelectron spectroscopy (XPS), it was found that aluminum oxide was formed.

The measurement of the Al element constituent proportion of the base material after the sputtering treatment and the measurement of the autohesion test were performed in the same manner as in Example 1.

The results are shown in Table 6. For comparison, Table 6 also shows Comparative Example 1 in which sputtering treatment was not performed.

TABLE 6

| | Al proportion | Test results | |
|---|---|---|---|
| Test No. | [at %] | Room temperature | 70° C. |
| Comparative | 0 | Adhesive | Adhesive |
| Example 1 | | | |
| Example 26 | 0.1 | Non-adhesive | Slightly adhesive |
| Example 27 | 0.3 | Non-adhesive | Slightly adhesive |
| Example 28 | 0.5 | Non-adhesive | Non-adhesive |
| Example 29 | 0.8 | Non-adhesive | Non-adhesive |

As shown in Table 6, in Comparative Example 1, no sputtering treatment was performed, and autohesion was confirmed at both room temperature and 70° C. In Examples 26 to 29, the films became non-adhesive through sputtering treatment. In particular, in Examples 28 and 29 in which the Al proportion was 0.5 at % or more, the films were non-adhesive even under more severe conditions (70° C.).

In addition, the stretchable base material having Al obtained in Example 26 was subjected to a cytotoxicity test defined by ISO10993-5, but no toxicity was observed. The reason for this is considered to be that the amount of Al formed on the surface by this method is extremely small, and because of the small amount, the surface is stabilized with an oxide. From this result, it is considered that the safety of the stretchable base material obtained by this method is shown.

### Seventh Example

### Examples 30 to 33

Two urethane-based elastomer films were prepared. These urethane-based elastomer films were subjected to a sputtering treatment using Al metal in the same manner as in Example 26.

After the sputtering treatment, the surfaces subjected to the sputtering treatment were superimposed on each other, and an autohesion test was performed in the same manner as in Example 26.

The results are shown in Table 7. For comparison, Table 6 also shows Comparative Example 3 in which sputtering was not performed.

TABLE 7

| | Al proportion | Test results | |
|---|---|---|---|
| Test No. | [at %] | Room temperature | 70° C. |
| Comparative | 0 | Adhesive | Adhesive |
| Example 3 | | | |
| Example 30 | 0.2 | Non-adhesive | Slightly |
| | | | adhesive |
| Example 31 | 0.3 | Non-adhesive | Slightly |
| | | | adhesive |
| Example 32 | 0.5 | Non-adhesive | Non-adhesive |
| Example 33 | 1.0 | Non-adhesive | Non-adhesive |

As shown in Table 7, in Comparative Example 3, no sputtering treatment was performed, and autohesion was confirmed at both room temperature and 70° C. In Examples 30 to 33, the films became non-adhesive through sputtering treatment. In particular, in Examples 32 and 33 in which the Al proportion was 0.5 at % or more, the films were non-adhesive even under more severe conditions (70° C.).

### Eighth Example

### Examples 34 to 39

Two urethane-based elastomer films were prepared. These urethane-based elastomer films were subjected to a sputtering treatment using the metals listed in Table 8 in the same manner as in Example 26.

After the sputtering treatment, the surfaces subjected to the sputtering treatment were superimposed on each other, and an autohesion test was performed in the same manner as in Example 26.

The results are shown in Table 8.

TABLE 8

| | | Metal | | |
|---|---|---|---|---|
| | | proportion | Test results | |
| Test No. | Metal | [at %] | Room temperature | 70° C. |
| Example 34 | Fe | 1.2 | Non-adhesive | Slightly |
| | | | | adhesive |
| Example 35 | Ni | 0.7 | Non-adhesive | Slightly |
| | | | | adhesive |
| Example 36 | Au | 0.9 | Non-adhesive | Non-adhesive |
| Example 37 | Pt | 1.5 | Non-adhesive | Non-adhesive |
| Example 38 | Ag | 0.8 | Non-adhesive | Non-adhesive |
| Example 39 | Ti | 2.1 | Non-adhesive | Non-adhesive |

As shown in Table 8, it was found that when Fe, Ni, Au, Pt, Ag, or Ti was used, the effect of suppressing autohesion between the stretchable base materials was obtained. It has been confirmed that autohesion can be suppressed by forming a metal or metal oxide film on the base material. It is considered that when not only Al and the metals listed in Table 8 but also other metals are used, a film capable of suppressing molecular diffusion can be formed because of the presence of a small amount of metal on the base material, and a similar effect can be obtained.

### Ninth Example

### Example 40

Two styrene-based elastomer films were prepared. These styrene-based elastomer films were subjected to plasma treatment.

### [Plasma Treatment]

The plasma treatment was performed using a PC-1000 (Samco Inc.).

As a result of measurement using X-ray photoelectron spectroscopy (XPS), it was found that aluminum oxide was formed on the films after plasma treatment. The proportion of aluminum atoms in the surface subjected to the plasma treatment was 0.8 at % with respect to all the elements.

After the plasma treatment, the surfaces subjected to the plasma treatment were superimposed on each other, and an autohesion test was performed. In the autohesion test, it was confirmed that there was no adhesion between elastomers.

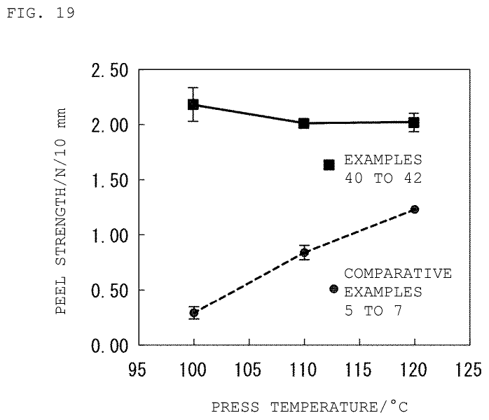

After the plasma treatment, the base material was press-bonded to a nylon-based base material with a polyester urethane-based adhesive interposed therebetween at 100 to 120° C. for 1 minute. The pressure was set to 0.6 MPa. Thereafter, as shown in FIG. 17, a 180° peel test was performed. The results are shown in FIGS. 18 and 19. FIG. 18 shows the result of the peel strength of 2.19 N·10 mm⁻¹ using the base material of Example 40 and the result of 0.28 N· 10 mm⁻¹ using the base material of Comparative Example 5.

### [180° Peel Test (Peel Strength)]

A 180° peel test was performed with reference to the 180° peel test for adhesive tape of JIS Z0237 and the test method of JIS Z0238 for heat-sealed soft packaging bags and semi-rigid containers. Specifically, the base material 80C and a nylon-based base material 92 after plasma treatment were bonded to each other with an adhesive layer 91 made of an adhesive interposed therebetween, and a tensile force F pulling the base material 80C and the nylon-based base material 92 in a direction away from each other, that is, in a direction away from each other by 180° was applied to the base material 80C and the nylon-based base material 92 to peel them. A force gauge was used to measure the peel strength. An aluminum oxide as the metal-containing region 81d was present on the surface of the base material 80C on the adhesive layer 91 side.

### Examples 41 and 42

After the plasma treatment, a peel test was performed in the same manner as in Example 40 except that the press temperature was changed.

### Comparative Example 5

Two styrene-based elastomer films were prepared in the same manner as in Example 40. Styrene-based elastomer films were superposed on each other, and an autohesion test was performed. In addition, a 180° peel test was performed as illustrated in FIG. 17. In Comparative Example 5, unlike FIG. 17, plasma treatment was not performed, and aluminum oxide was not formed. Among the measurement results of the two peel strengths shown in FIG. 18, in Comparative Example 5, the peel strength had the low value of 0.28 N·10 mm⁻¹.

### Comparative Examples 6 and 7

After the plasma treatment, a peel test was performed in the same manner as in Comparative Example 5 except that the press temperature was changed.

The results are shown in Table 9.

TABLE 9

| | | Proportion | Results of autohesion test | | | Peel strength |
|---|---|---|---|---|---|---|
| | Plasma | of aluminum | Room | | Press | (average value |
| Test No. | treatment | (at %) | temperature | 70° C. | temperature | of N = 3) |
| Example 40 | Treated | 0.8 | Non-adhesive | Non-adhesive | 100° C. | 2.19 |
| Example 41 | Treated | | Non-adhesive | Non-adhesive | 110° C. | 2.01 |
| Example 42 | Treated | | Non-adhesive | Non-adhesive | 120° C. | 2.02 |
| Comparative | Not | 0 | Adhesive | Adhesive | 100° C. | 0.28 |
| Example 5 | treated | | | | | |
| Comparative | Not | | Adhesive | Adhesive | 110° C. | 0.84 |
| Example 6 | treated | | | | | |
| Comparative | Not | | Adhesive | Adhesive | 120° C. | 1.23 |
| Example 7 | treated | | | | | |

As shown in Table 9 and FIG. 18, in Example 40 in which the plasma treatment was performed, the peel strength in the 180° peel test was larger than that in Comparative Example 5 in which the plasma treatment was not performed. That is, the adhesion strength was increased by performing the plasma treatment.

In FIG. 19, the results of Examples 40 to 42 are represented by black squares, and the results of Comparative Examples 5 to 7 are represented by black circles. As shown in Table 9 and FIG. 19, in Examples 40 to 42, the variation in peel strength was small even when the press temperature varied, and good peel strength was able to be maintained regardless of the difference in press temperature. On the other hand, in Comparative Examples 5 to 7, the peel strength was smaller than that in Examples 40 to 42, and the peel strength was affected by the variation in the press temperature. Specifically, in Comparative Examples 5 to 7, peeling was more likely to occur as the press temperature decreased. As described above, in Examples 40 to 41, it was found that high peel strength can be obtained even at a low press temperature. By being able to firmly adhere at a low temperature, the load generated by the heat treatment on the stretchable substrate and the wire is reduced.

In Examples 1 to 22 and 24 to 42 and Reference Example 23 described above, the physical properties are measured using only the base material, but the physical properties can be measured in the same manner when a wire is attached.

The present disclosure is not limited to the above-described embodiments, and can be changed in design without departing from the gist of the present disclosure. For example, the respective features of the first to fourth embodiments may be combined in various manners.

### DESCRIPTION OF REFERENCE SYMBOLS

100, 100A, 100B, 100C, 100D, 100E: Stretchable device
1, 1A, 1B, 1C: Stretchable substrate
2: Wire
3: Sheet material
4A: First shape
4B: Second shape
4a1, 4b1: Protrusion
4a2, 4b2: Recessed groove
5, 5C: Embossing sheet material
5a1: Warp yarn portion
5b1: Weft yarn portion
61: White portion
62: Coarse dot portion
63: Fine dot portion
71: First portion
72: Second portion
80, 82, 83: Base material
81: Metal-containing portion

1. A stretchable substrate having a first main surface and a second main surface facing opposite of each other, wherein the stretchable substrate satisfies at least one of (1) to (4):
(1) at least either the first main surface or the second main surface has an oxygen atomic proportion of 5 at % or more with respect to all atoms as measured by X-ray photoelectron spectroscopy;
(2) the first main surface or the second main surface has an arithmetic average surface roughness of 6 μm or more as measured with a laser microscope;
(3) at least either the first main surface or the second main surface includes a metal-containing portion containing a metal atom; or
(4) a metal-containing region containing a metal atom that is positioned along at least either the first main surface or the second main surface.

2. The stretchable substrate according to claim 1, wherein the stretchable substrate has the oxygen atomic proportion of at least either the first main surface or the second main surface is 5 at % or more with respect to all atoms as measured by the X-ray photoelectron spectroscopy.

3. The stretchable substrate according to claim 1, wherein the first main surface and the second main surface of the stretchable substrate have an oxygen atomic proportion of 5 at % or less in a central portion in a direction orthogonal to the first main surface and the second main surface.

4. The stretchable substrate according to claim 1, wherein the stretchable substrate has the arithmetic average surface roughness of the surface of the first main surface or the second main surface of 6 μm or more as measured with the laser microscope.

5. The stretchable substrate according to claim 1, wherein the stretchable substrate has at least either the first main surface or the second main surface that includes the metal-containing portion containing the metal atom.

6. The stretchable substrate according to claim 5, wherein the first main surface or the second main surface of the stretchable substrate has a constituent proportion of a metal in the metal-containing portion to all elements of 0.5 at % or more as measured by X-ray photoelectron spectroscopy.

7. The stretchable substrate according to claim 5, wherein the first main surface and the second main surface the stretchable substrate has an oxygen atomic proportion of 5 at % or less in a central portion in a direction orthogonal to the first main surface and the second main surface.

8. The stretchable substrate according to claim 1, wherein the stretchable substrate has the metal-containing region containing the metal atom positioned along at least either the first main surface or the second main surface.

9. The stretchable substrate according to claim 8, wherein the first main surface or the second main surface has a proportion of the metal atom of 0.2 at % to 2.5 at %.

10. The stretchable substrate according to claim 5, wherein the metal atom includes at least one selected from the group consisting of Al, Fe, Ni, Au, Pt, Ag, and Ti.

11. The stretchable substrate according to claim 1, wherein the stretchable substrate comprises a rubber or an elastomer.

12. A stretchable device comprising:
the stretchable substrate according to claim 1; and
a wire on the first main surface of the stretchable substrate.

13. A stretchable device comprising:
the stretchable substrate according to claim 5;
a wire on the first main surface of the stretchable substrate; and
a protective layer covering the wire,
wherein the second main surface includes the metal-containing portion.

14. A method for producing a stretchable substrate, the method comprising:
preparing a base material; and
performing an ozone treatment on at least either a first main surface of the base material or a second main surface on an opposite side of the base material from the first main surface.

15. The method for producing a stretchable substrate according to claim 14, wherein the stretchable substrate contains 5 at % or more of oxygen atoms on at least either the first main surface or the second main surface.

16. The method for producing a stretchable substrate according to claim 14, further comprising embossing at least either the first main surface or the second main surface after the ozone treatment.

17. A method for producing a stretchable device, the method comprising:
preparing a base material having a first main surface and a second main surface facing opposite of each other;
disposing a wire on the first main surface of the base material; and
performing an ozone treatment on at least either the first main surface or the second main surface after the disposing of the wire.

18. A method for producing a stretchable device, the method comprising:
preparing a base material having a first main surface and a second main surface facing opposite of each other;
disposing a wire on the first main surface of the base material; and
embossing at least either the first main surface or the second main surface after the disposing of the wire.

19. A method for producing a stretchable device, the method comprising:
preparing a first base material having a first main surface and a second main surface facing opposite of each other; and
forming a metal-containing portion in at least either the first main surface or the second main surface of the first base material.

20. The method for producing a stretchable device according to claim 19, the method further comprising:
disposing a wire on the first main surface of the first base material the forming of the metal-containing portion;
preparing a second base material including a first main surface and a second main surface facing opposite of each other; and
disposing the first main surface of the second base material on the wire.
